(19) United States
(12) Patent Application Publication
(10) Pub. No.: US 2024/0086598 A1
(43) Pub. Date: Mar. 14, 2024

(54) TRANSFORMING A MODEL IN A FIRST LANGUAGE TO A SURROGATE IN A SECOND LANGUAGE FOR SIMULATION

(71) Applicant: JuliaHub, Inc., Boston, MA (US)

(72) Inventors: Christopher Rackauckas, Cambridge, MA (US); Viral B. Shah, Cambridge, MA (US)

(21) Appl. No.: 18/505,733

(22) Filed: Nov. 9, 2023

Related U.S. Application Data
(63) Continuation of application No. PCT/US22/28614, filed on May 10, 2022.
(60) Provisional application No. 63/186,555, filed on May 10, 2021.
(60) Provisional application No. 63/288,697, filed on Dec. 13, 2021.

(51) Int. Cl. G06F 30/27; G06F 40/47

(52) U.S. Cl. CPC G06F 30/27; G06F 40/47

(57) ABSTRACT

Methods and computer systems for transforming a model of a first scientific computing language to a model (e.g., surrogate) of a second scientific computing language such that the surrogate is trained across a plurality of possible inputs is disclosed. Model inputs in a first scientific computing language are received. A surrogate is generated based on the received model input. The surrogate may be trained across a plurality of possible inputs by selecting an input function representation for the model input, selecting a parameter space, sampling the parameter space to generate a training set of time series for each parameter set, simulating a reservoir, computing projections from the simulated reservoir, and fitting an interpolating function between the projections to establish an approximate projection for unknown input functions and parameter values. The surrogate is then deployed, either trained or untrained depending on the embodiment.

### CROSS REFERENCE TO RELATED APPLICATIONS

This application is a bypass continuation of PCT Patent Application No. PCT/US2022/028614 filed on May 10, 2022, by JuliaHub, Inc., entitled “TRANSFORMING A MODEL IN A FIRST LANGUAGE TO A SURROGATE IN A SECOND LANGUAGE FOR SIMULATION,” which claims priority to U.S. Provisional Patent Application No. 63/186,555 filed on May 10, 2021, by JuliaHub, Inc., entitled “TRANSFORMING A MODEL IN A FIRST LANGUAGE TO A SURROGATE IN A SECOND LANGUAGE FOR SIMULATION,” and to U.S. Provisional Patent Application No. 63/288,697 filed on Dec. 13, 2021, by JuliaHub, Inc., entitled “TRANSFORMING A MODEL IN A FIRST LANGUAGE TO A SURROGATE IN A SECOND LANGUAGE FOR SIMULATION,” the entire contents of each of which are incorporated by reference herein.

### GOVERNMENT SUPPORT

This invention was made with U.S. Government support under ARPA-E Award No. DE-AR0001222, awarded by ARPA-E. The Government has certain rights in this invention.

### TECHNICAL FIELD

The field of the invention relates generally to methods and systems for improving scientific computing. More specifically, the field of the invention relates to methods and systems for transforming a model in a first scientific computing language into a surrogate in a second scientific computing language.

### BACKGROUND

Various scientific computing languages are used for modeling and/or simulating complex physical problems. Different languages may be used for different types of problems to be modeled/simulated. An issue arises when models from different computing languages are sought to be used together. The models are not necessarily interchangeable between languages, but many of the models may be coupled to one another using the output. Such coupling, however, has problems. For example, the coupling of the various modeling tools is not very efficient, which means that trying to run coupled models can be slow and/or resource intensive.

Various solutions have been proposed. For example, the Functional Mockup Interface (“FMI”) is a standard interface that can be used to couple together models from different languages that output time-series values. The FMI-based approach has many known issues. First, it is not compatible with all modeling languages. Second, translating models to the FMI standard can reduce performance. Third, the constraints of the FMI interface can reduce the stability of the numerical simulation, thus making some models not able to be numerically simulated with the interface.

Accordingly, there is a need for methods and systems that provide for interchangeability of models across various commercially available simulation tools.

### SUMMARY

This summary is provided to introduce a selection of concepts in simplified form that are further described below in the detailed description. This summary is not intended to identify key features or essential features of the claimed subject matter, nor is it intended to be used to limit the scope of the claimed subject matter.

Disclosed herein are methods and computer systems that provide a translator that takes as input a model in a first scientific computing language and uses machine learning to generate a surrogate in a second scientific computing language. The generated surrogate is trained in the second scientific computing language using the outputs from the model in the first scientific computing language. The generated surrogate may be used directly in a simulation with the second language, thereby avoiding the need for coupling or other types of interfacing between two different scientific computing languages.

The methods and computer systems described herein solve the above-identified problems by transforming a model in a first scientific computing language into a model (e.g., a surrogate) in a second scientific computing language. In one embodiment, the methods and computer systems provide surrogate acceleration of models and incorporate them into Julia Computing' s ModelingToolkit.jl modeling language. This gives an alternative to Simulink or Modelica that is designed to integrate with all of the scientific machine learning tooling, allowing for more speed while giving unique features such as automated model discovery. Additionally, the methods and computer systems described herein may be integrated with a library of premade models that make it easy for users (e.g., scientists and engineers) to get started in the model-building process. For example, Julia Computing's JuliaSim Model Library is an example of such a library of premade models. Premade models can be composed together, allowing for the quick generation and analysis of models by the newest simulation tools. An approach to generating premade models is disclosed in U.S. Provisional Patent App. No. 63/080,311 by Julia Computing, entitled “Systems and Methods of Component-Based Modeling Using Trained Surrogates,” filed on Sep. 18, 2020, and International Publication Number WO 2022/061142 A1, entitled “Systems and Methods of Component-Based Modeling Using Trained Surrogates,” published on Mar. 24, 2022, the entire contents of which are hereby incorporated by reference.

In some embodiments, the premade models may be provided in a pre-surrogatized form, which allows for surrogate accelerations to take place without requiring training on the side of the user. The premade models in Julia Computing's JuliaSim Model Library are examples of such pre-surrogatized models.

In a first embodiment in accordance with the present disclosure, a method of transforming a model of a first scientific computing language to a surrogate of a second scientific computing language such that the surrogate is trained across a plurality of possible inputs is disclosed. The method includes receiving a model input. The model input is of a first scientific computing language. The method further includes generating a surrogate based on the received model input. The surrogate is of a second scientific computing language, and the second scientific computing language is different from the first scientific language. The method further includes training the surrogate across a plurality of possible inputs. Training the surrogate includes selecting an input function representation for each of one or more continuous input functions for the model input. Each input function representation is a finite parameter list. Training the surrogate further includes selecting a parameter space. The parameter space is a cross product of ranges of parameters, and the parameters include a concatenation of parameters of the original system and parameters of the input function representations. Training the surrogate further includes sampling the parameter space to generate a training set of time series for each parameter set. Training the surrogate further includes simulating a reservoir. Training the surrogate further includes computing projections from the simulated reservoir to each time series in the training set. Training the surrogate further includes fitting an interpolating function between the projections to establish an approximate projection for unknown input functions and parameter values. The method further includes deploying the trained surrogate.

In a second embodiment in accordance with the present disclosure, a method of transforming a model of a first scientific computing language to a surrogate of a second scientific computing language such that the surrogate is trained across a plurality of possible inputs is disclosed. The method includes receiving a model input. The model input is of a first scientific computing language. The method further includes generating a surrogate based on the received model input. The method further includes training the surrogate across a plurality of possible inputs. Training the surrogate includes selecting an input function representation for each of one or more continuous input functions for the model input. Each input function representation is a finite parameter list. Training the surrogate further includes selecting a parameter space. The parameter space is a cross product of ranges of parameters, and the parameters include a concatenation of parameters of the original system and parameters of the input function representations. Training the surrogate further includes sampling the parameter space to generate a training set of time series for each parameter set. Training the surrogate further includes simulating a reservoir. Training the surrogate further includes computing projections from the simulated reservoir to each time series in the training set. Training the surrogate further includes fitting an interpolating function between the projections to establish an approximate projection for unknown input functions and parameter values. The method further includes deploying the trained surrogate.

In various embodiments, the surrogate is of a second scientific computing language. The second scientific computing language may be different from the first scientific computing language.

In various embodiments, the representations are selected to be coefficients of Chebyshev polynomials, Fourier series amplitudes and frequencies, or polynomial expansion coefficients.

In various embodiments, the projections are computed using QR decomposition or singular value decomposition.

In various embodiments, the simulated reservoir is selected such that the time series from the reservoir matches key characteristics of the output time series.

In various embodiments, the simulated reservoir includes a discontinuity at a point in time in which the time series contains a discontinuity.

In various embodiments, the simulated reservoir is domain-specific.

In some embodiments, the method further includes using an external forcing function to train the surrogate. The external forcing function may be a Fourier series or a polynomial with a finite number of terms and a predefined range of coefficients. In an embodiment, the simulated reservoir is excited using the external forcing function.

In various embodiments, the model input is a proprietary model. The proprietary model may be a model in the Julia computing language.

In various embodiments, the model input is a functional mockup unit (FMU) model.

In various embodiments, the surrogate is generated using a Continuous Time Echo State Networks (CTESN) algorithm. The CTESN may be a linear projection CTESN (LPCTESN).

In various embodiments, generating the surrogate is automated by simulation of FMUs using an FMU simulation layer. Generating the surrogate may further include training an automated data-driven method on the results.

In various embodiments, the training of the surrogate is performed using machine learning.

In various embodiments, the trained surrogate is an approximation that is built on a time series or an approximation that includes steady-state behavior of the received model input.

In various embodiments, deploying the trained surrogate includes connecting the trained surrogate with a separate user-defined model using a model composition framework, coupling the trained surrogate with a separate FMU model, or using the trained surrogate in an optimization loop for design. The model composition framework may be an acausal modeling framework, a causal modeling framework, a co-simulation framework, or a model exchange framework.

In various embodiments, the first scientific computing language is Modelica or Verilog-A. In various embodiments, the second scientific computing language is Julia.

In a third embodiment in accordance with the present disclosure, a computer system for transforming a model of a first scientific computing language to a surrogate of a second scientific computing language such that the surrogate is trained across a plurality of possible inputs. The computer system includes a memory and a processor. The processor is configured for receiving a model input. The model input is of a first scientific computing language. The processor is further configured for generating a surrogate based on the received model input. The surrogate is of a second scientific computing language, and the second scientific computing language is different from the first scientific computing language. The processor is further configured for training the surrogate across a plurality of possible inputs. Training the surrogate includes selecting an input function representation for each of one or more continuous input functions for the model input. Each input function representation is a finite parameter list. Training the surrogate further includes selecting a parameter space. The parameter space is a cross product of ranges of parameters, and the parameters include a concatenation of parameters of the original system and parameters of the input function representations. Training the surrogate further includes sampling the parameter space to generate a training set of time series for each parameter set. Training the surrogate further includes simulating a reservoir. Training the surrogate further includes computing projections from the simulated reservoir to each time series in the training set. Training the surrogate further includes fitting an interpolating function between the projections to establish an approximate projection for unknown input functions and parameter values. The processor is further configured for deploying the trained surrogate.

In a fourth embodiment in accordance with the present disclosure, a computer system for transforming a model of a first scientific computing language to a surrogate of a second scientific computing language such that the surrogate is trained across a plurality of possible inputs. The computer system includes a memory and a processor. The processor is configured for receiving a model input. The model input is of a first scientific computing language. The processor is further configured for generating a surrogate based on the received model input. The processor is further configured for training the surrogate across a plurality of possible inputs. Training the surrogate includes selecting an input function representation for each of one or more continuous input functions for the model input. Each input function representation is a finite parameter list. Training the surrogate further includes selecting a parameter space. The parameter space is a cross product of ranges of parameters, and the parameters include a concatenation of parameters of the original system and parameters of the input function representations. Training the surrogate further includes sampling the parameter space to generate a training set of time series for each parameter set. Training the surrogate further includes simulating a reservoir. Training the surrogate further includes computing projections from the simulated reservoir to each time series in the training set. Training the surrogate further includes fitting an interpolating function between the projections to establish an approximate projection for unknown input functions and parameter values. The processor is further configured for deploying the trained surrogate.

In various embodiments, the surrogate is of a second scientific computing language. The second scientific computing language may be different from the first scientific computing language.

In various embodiments, the representations are selected to be coefficients of Chebyshev polynomials, Fourier series amplitudes and frequencies, or polynomial expansion coefficients.

In various embodiments, the projections are computed using QR decomposition or singular value decomposition.

In various embodiments, the simulated reservoir is selected such that the time series from the reservoir matches key characteristics of the output time series.

In various embodiments, the simulated reservoir includes a discontinuity at a point in time in which the time series contains a discontinuity.

In various embodiments, the simulated reservoir is domain-specific.

In various embodiments, the processor is further configured for using an external forcing function to train the surrogate. The external forcing function may be a Fourier series or a polynomial with a finite number of terms and a predefined range of coefficients. The simulated reservoir may be excited using the external forcing function.

In various embodiments, the model input is a proprietary model. The proprietary model may be a model in the Julia computing language.

In various embodiments, the model input is a functional mockup unit (FMU) model.

In various embodiments, the surrogate is generated using a Continuous Time Echo State Networks (CTESN) algorithm. The CTESN may be a linear projection CTESN (LPCTESN).

In various embodiments, generating the surrogate is automated by simulation of FMUs using an FMU simulation layer. Generating the surrogate may further include training an automated data-driven method on the results.

In various embodiments, the training of the surrogate is performed using machine learning.

In various embodiments, the trained surrogate is an approximation that is built on a time series or an approximation that includes steady-state behavior of the received model input.

In various embodiments, deploying the trained surrogate includes connecting the trained surrogate with a separate user-defined model using a model composition framework, coupling the trained surrogate with a separate FMU model, or using the trained surrogate in an optimization loop for design. The model composition framework may be an acausal modeling framework, a causal modeling framework, a co-simulation framework, or a model exchange framework.

In various embodiments, the first scientific computing language is Modelica or Verilog-A. In some embodiments, the second scientific computing language is Julia.

In a fifth embodiment in accordance with the present disclosure, a method of transforming a model of a first scientific computing language to a surrogate of a second scientific computing language is disclosed. The method includes receiving a model input. The model input is of a first scientific computing language. The method further includes generating a surrogate based on the received model input. The surrogate is of a second scientific computing language, and the second scientific computing language is different from the first scientific computing language. The method further includes deploying the generated surrogate.

In a sixth embodiment in accordance with the present disclosure, a method of transforming a model of a first scientific computing language to a surrogate of a second scientific computing language is disclosed. The method includes receiving a model input. The model input is of a first scientific computing language. The method further includes generating a surrogate based on the received model input. The surrogate is of a second scientific computing language. The method further includes deploying the generated surrogate.

In various embodiments, the second scientific computing language is different from the first scientific computing language

In various embodiments, the model input is a proprietary model. The proprietary model may be a model in the Julia computing language.

In various embodiments, the model input is a functional mockup unit (FMU) model.

In various embodiments, the surrogate is generated using a Continuous Time Echo State Networks (CTESN) algorithm. The CTESN may be a linear projection CTESN (LPCTESN).

In various embodiments, generating the surrogate is automated by simulation of FMUs using an FMU simulation layer. Generating the surrogate may further include training an automated data-driven method on the results.

In various embodiments, the generation of the surrogate is performed using machine learning.

In various embodiments, the generated surrogate is an approximation that is built on a time series or an approximation that includes steady-state behavior of the received model input.

In various embodiments, deploying the generated surrogate includes connecting the generated surrogate with a separate user-defined model using a model composition framework, coupling the generated surrogate with a separate FMU model, or using the generated surrogate in an optimization loop for design. The model composition framework may be an acausal modeling framework, a causal modeling framework, a co-simulation framework, or a model exchange framework.

In various embodiments, the first scientific computing language is Modelica or Verilog-A. In various embodiments, the second scientific computing language is Julia.

In a seventh embodiment in accordance with the present disclosure, a computer system for transforming a model of a first scientific computing language to a surrogate of a second scientific computing language is disclosed. The computer system includes a memory and a processor. The processor is configured for receiving a model input. The model input is of a first scientific computing language. The processor is further configured for generating a surrogate based on the received model input. The surrogate is of a second scientific computing language, and the second scientific computing language is different from the first scientific computing language. The processor is further configured for deploying the generated surrogate.

In an eighth embodiment in accordance with the present disclosure, a computer system for transforming a model of a first scientific computing language to a surrogate of a second scientific computing language is disclosed. The computer system includes a memory and a processor. The processor is configured for receiving a model input. The model input is of a first scientific computing language. The processor is further configured for generating a surrogate based on the received model input. The surrogate is of a second scientific computing language. The processor is further configured for deploying the generated surrogate.

In various embodiments, the second scientific computing language is different from the first scientific computing language

In various embodiments, the model input is a proprietary model. The proprietary model may be a model in the Julia computing language.

In various embodiments, the model input is a functional mockup unit (FMU) model.

In various embodiments, the surrogate is generated using a Continuous Time Echo State Networks (CTESN) algorithm. The CTESN may be a linear projection CTESN (LPCTESN).

In various embodiments, generating the surrogate is automated by simulation of FMUs using an FMU simulation layer. Generating the surrogate may further include training an automated data-driven method on the results.

In various embodiments, the generation of the surrogate is performed using machine learning.

In various embodiments, the generated surrogate is an approximation that is built on a time series or an approximation that includes steady-state behavior of the received model input.

In various embodiments, deploying the generated surrogate includes connecting the generated surrogate with a separate user-defined model using a model composition framework, coupling the generated surrogate with a separate FMU model, or using the generated surrogate in an optimization loop for design. The model composition framework may be an acausal modeling framework, a causal modeling framework, a co-simulation framework, or a model exchange framework.

In various embodiments, the first scientific computing language is Modelica or Verilog-A. In various embodiments, the second scientific computing language is Julia.

In these ways, the methods and systems described herein improve the functioning of a computer performing scientific computing by teaching methods and systems that allow premade models that were generated in a first scientific computing language to be used natively in a second scientific computing language. The transformation allows for scientists and engineers to be more productive by automating the language change process while resulting in more efficient simulation.

### BRIEF DESCRIPTION OF THE DRAWINGS

The present embodiments are illustrated by way of example and are not intended to be limited by the figures of the accompanying drawings.

FIG. 1 depicts a process flow of an exemplary method of transforming a model in a first scientific computing language into a surrogatized model.

FIG. 2A depicts an exemplary process flow of a method for transforming a model of a first scientific computing language to a surrogate such that the surrogate is trained across a plurality of possible inputs.

FIG. 2B depicts an exemplary process flow of a method for training the surrogate across a plurality of possible inputs for scientific computing.

FIG. 3 shows rich response dynamics of a domain-specific reservoir used in the NR-CTESN, used to generate the surrogate of the inverter.

FIG. 4 shows a prediction of surrogate to unseen test input sequence.

FIG. 5 shows relative error of surrogate prediction at test input sequence.

FIG. 6 shows a histogram of test errors.

FIG. 7 depicts a block diagram illustrating one embodiment of a computing device that implements the methods and systems for transforming a model in a first scientific computing language into a surrogatized model in a second scientific computing language described herein.

### DETAILED DESCRIPTION

The following description and figures are illustrative and are not to be construed as limiting. Numerous specific details are described to provide a thorough understanding of the disclosure. In certain instances, however, well-known or conventional details are not described in order to avoid obscuring the description. References to “one embodiment” or “an embodiment” in the present disclosure may be (but are not necessarily) references to the same embodiment, and such references mean at least one of the embodiments.

Machine learning has been shown to be effective in problems such as language translation, as well as for performing tasks like generating surrogates of dynamical systems. As described herein, those two roles can be performed in tandem by using surrogates to develop approximate translations of models made using a first scientific computing language into surrogates in a second scientific computing language. For example, in one embodiment, the methods and computer systems disclosed herein use surrogates to develop approximate translations of Modelica models into Julia-based ModelingToolkit.jl components. In another embodiment, the methods and computer systems disclosed herein use surrogates to develop approximate translations of Verilog-A models into Julia-based ModelingToolkit.jl components.

Machine learning and data-driven model order reduction techniques, such as continuous-time echo state networks (CTESNs), neural ordinary differential equations (ODEs), physics-informed neural networks, transformers, recurrent neural networks (RNNs), radial basis functions, radial basis networks, dynamic mode decomposition, balanced truncation, proper orthogonal decomposition, Lift & Learn, sparse identification of dynamical systems (SINDy), symbolic regression, and long short-term memory networks (LSTMs), can be used to build surrogates directly from simulated data, giving a data-driven model approximate translation. These surrogates can be simultaneously trained with real data to generate digital twins which improve the predictive performance of the models.

The Functional Mockup Interface (“FMI”) standard is an open-source standard for coupled simulation that has been adopted and supported by many simulation tools, both open-source and commercial. Models can be exported as Functional Mockup Units (“FMUs”), which can then be simulated in a shared environment. Two forms of coupled simulation are standardized. Model exchange uses a centralized time-integration algorithm to solve the coupled sets of differential-algebraic equations (“DAEs”) exported by the individual FMUs. The second approach, co-simulation, allows FMUs to export their own simulation routine, and synchronizes them using a master algorithm. However, this resulting coupled simulation using FMUs is computationally expensive, making design, optimization, and control design intractable. This is due to the resulting numerical stiffness from widely separated time constants. For example, building heat transfer dynamics has time constants in hours whereas feedback controllers have time constants in seconds. These simulations require adaptive implicit integrators to step forward in time. This necessitates the use of surrogate models that alleviate the computational burden, while maintaining reasonable accuracy.

FMUs are model binaries that can be produced from popular simulation tools such as Simulink, CATIA, and Ansys products. Companies are known to use FMUs as the core architecture for preserving models. Common software for generating FMUs includes, for example, Mathworks tools like Simulink, Ansys tools like SCADE, CATIA, MapleSim, Mathematica, and Modelica software like Dymola and OpenModelica. Any of these, as well as others that are not listed here, may be included in the term “scientific computing language” as referred to herein. This also includes, for example, direct implementation of models in a programming language or a modeling language, such as Python, R, MATLAB, C, C++, Fortran, or the like.

The methods and computer systems disclosed herein take advantage of any representation of a simulation's output (of which the FMI standard is one example) and generate a surrogate model of this piece of the dynamical system and generate a faster form of the simulation.

The methods and computer systems described herein may be used to automate the deployment of high-performance surrogate-accelerated models from any platform that supports the Functional Mockup Interface (“FMI”) standard. The surrogates can then be embedded in a different simulation environment for design, optimization, and control. For example, in one embodiment, the surrogates can then be embedded in a Julia simulation environment for design, optimization, and control.

The methods and computer systems described herein offer users a way to automatically “surrogatize” their models and thus accelerate their analysis. The training and deployment of surrogates may be automated for applications such as design, optimization, and co-simulation.

The surrogatized models generated as described herein may be connected using model composition frameworks, such as acausal modeling frameworks (including ModelingToolkit, Simscape, and Modelica), causal modeling frameworks (including Simulink), Co-simulation frameworks (such as FMI Cosimulation) and model exchange frameworks (such as FMI Model Exchange).

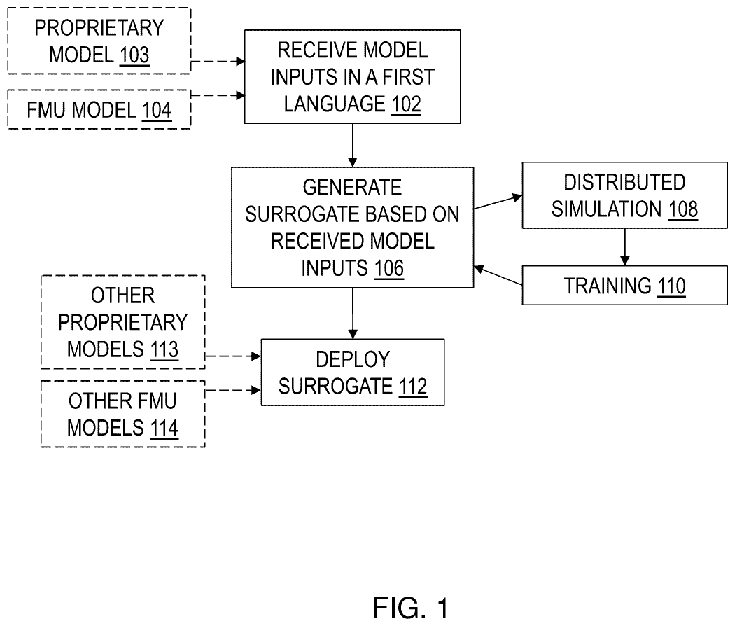

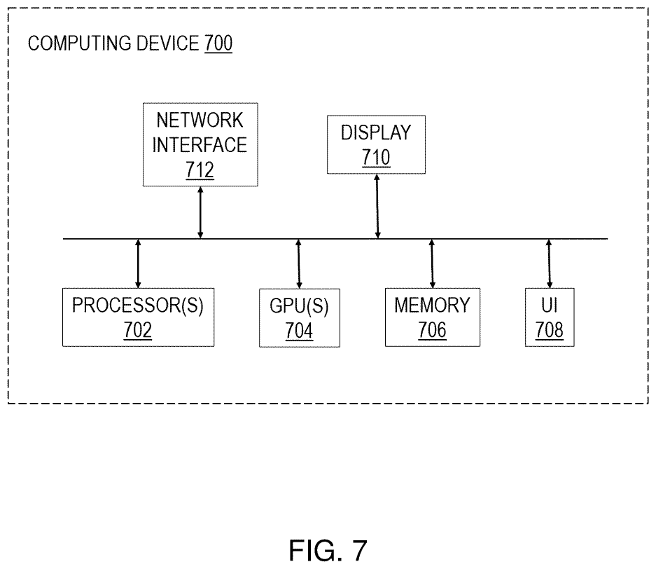

FIG. 1 depicts a process flow of an exemplary method of transforming a model in a first scientific computing language into a surrogatized model. As just one example, this process may be used to transform a Modelica model or a Verilog-A model into a Julia model. The method described in the context of FIG. 1 may be implemented by at least one processor or other circuitry in a computing device such as the exemplary computing device shown in FIG. 7 or a system comprising one or more computing devices such as the exemplary device shown in FIG. 7.

Referring to FIG. 1, the method begins with receiving model inputs at step 102. The model input is in a first scientific computing language. The first scientific computing language may be any scientific computing software and/or simulation software that provides output as time-series data. For example, the first scientific computing language may be Modelica, Verilog-A, Matlab, Simulink, Ansys tools, or the like. In various embodiments, the model inputs may optionally be received as a proprietary model (e.g., a Julia Computing ModelingToolkit model), as shown, for example, at step 103 and/or as an FMU model, as shown, for example, at step 104.

In one embodiment, the received model inputs may be for a Julia Computing ModelingToolkit (“MTK”) model. When receiving model inputs as a ModelingToolkit model, there may be additional benefits provided. For example, a ModelingToolkit model may further include automatic differentiation, as described, for example, in U.S. Provisional Patent App. No. 63/133,949 by Julia Computing, entitled “Compiler Transform Optimization for Non-Local Functions” and filed on Jan. 5, 2021, and International Application No. PCT/US2022/011245, entitled “Compiler Transform Optimization for Non-Local Functions,” filed on Jan. 5, 2022, the entire contents of which are hereby incorporated by reference. Automatic differentiation allows for training of the generated surrogate with dramatically less computational cost, though the FMU connection is given to allow for connecting to these other markets.

The method of FIG. 1 generates and deploys surrogates for optimization and co-simulation. The surrogates are generated based on the received model inputs at step 106. In one embodiment, the surrogates may be generated from FMUs. In such embodiments, the generation of surrogates from FMUs may be automated via distributed simulation of FMUs using an FMU simulation layer (step 108) and training an automated data-driven method on the results (step 110).

In one embodiment, the generated surrogate is an approximation that is built on a time series of the received model input. In another embodiment, the generated surrogate is an approximation that includes steady-state behavior of the received model input.

In one embodiment, the surrogate may be generated using the Continuous Time Echo State Networks (CTESN) algorithm. In other embodiments, the methods and computer systems described herein use other data-driven surrogate methods as well.

The generated surrogate is then deployed, at step 112, in the form of generated equations, which can then be optionally coupled with other user-defined models 113 or FMUs 114, or be used in other analyses such as for controls, optimization, design, and sensitivity analysis.

The method described above in the context of FIG. 1 may be implemented on a computer system having a memory and at least one processor configured to execute the method described herein. The computer system may further use graphics processing units (GPUs) for high-performance processing of the models.

In one embodiment, the methods and computer systems described herein may be implemented as a cloud-based platform for modeling and simulation.

### Surrogatization Algorithm

As mentioned above in the context of FIG. 1, a surrogate is generated at step 106. The generation of the surrogate, or “surrogatization,” may be performed, in one embodiment, using a Continuous Time Echo State Networks (CTESN) algorithm. CTESN is a continuous-time generalization of Echo State Networks (ESNs). ESN is a reservoir computing framework for learning a non-linear map by projecting the inputs onto high-dimensional spaces through predefined dynamics of a non-linear system. Different variants of the CTESN framework may be supported, including Linear Projection CTESN (“LPCTESN”) and Non-Linear Projection CTESN (“NPCTESN”). LPCTESN may be defined with N R dimensional reservoir as:

r′=f(Ar+W_{hyb}x(p*,t))

x(t)=g (Wₒᵤₜr(t))

\hat{x}(t)=g(Wₒᵤₜ(\hat{p})(t))

where A is a fixed random sparse N_{R}×N_{R} matrix, W_{hyb} is a fixed random dense N_{R}×N matrix, and x(p*, t) is a solution of the system at a specific parameter set p*. The f and g functions are activation functions, and they may be set to functions such as tanh and identity, respectively. This formulation allows for learning the Wₒᵤₜ matrix by global L₂ fitting via stabilized methods like SVD. The prediction \hat{x}(t) is made using an interpolated Wₒᵤₜ (\hat{p}) matrix.

The ODE dynamics of NPCTESN are kept the same as those in LPCTESN (see r′=f (Ar+W_{hyb}x(p*, t)), above). To model the non-linear projection r(t)→x(t), learned polynomial coefficients βᵢ from radial basis function are used and then a mapping between the model parameters and βᵢ's is constructed.

rbf(βᵢ)(r(t))≈x(pᵢ, t)∀i∈{1, . . . ,k}

rbf(pᵢ)≈βᵢ∀i∈(1, . . . ,k}

where k is the total number of parameter samples used for training. The NPCTESN predicts the time series via:

\hat{β}=rbf(\hat{p})

\hat{x}(t)=rbf(\hat{β})(r((t))

Block models in modeling systems as described above are ordinary differential equations that allow for arbitrary input functions. This can be written as follows, where u are the states of the component, f is the input function, and y are the output observables. In such a mechanistic system modeling context, systems are composed by defining the f(t) by the output observables y(t) of another block.

u′=φ(u,p,t,f(t))

y=ψ(u)

Developing a surrogate architecture capable of being used in such a context thus boils down to developing continuous-time surrogates capable of capturing the system response of non-linear systems.

### Nonlinear Response Continuous-Time Echo State Networks (NR-CTESN)

In some embodiments, the generation of the surrogates may be further extended to work with fully causal and acausal systems with continuous and semi-continuous input functions, which allows for the systems and computer systems described herein to cover a wider space of models. As explained above, the methods and computer systems described above provide for using CTESN surrogates, for example, to transform a model of a first scientific computing language to a surrogate of a second scientific computing language. The examples described above showcased the surrogate translation setting with discrete or constant input values and parameters. However, the methods and computer systems described above may be extended to work with fully causal and acausal systems with continuous and semi-continuous input functions. The following examples describe a technique for training such a CTESN surrogate with arbitrary continuous input functions.

In one embodiment of the methods and computer systems described herein, a Nonlinear Response CTESN (NR-CTESN) extension is used to train the surrogate over all possible inputs. As described above, CTESNs are a continuous-time analogue of Echo State Networks, which are a form of reservoir computing, and they comprise two parts: (1) a reservoir Ordinary Differential Equation (ODE), which is cheap to simulate by design, and (2) a projection operator from this reservoir to the reference system. While the reservoir ODE is designed by the user based on various considerations, the projection operator is trained using a linear least-squares solve. As explained above, a CTESN may be formulated as follows:

r′=g(Ar+W_{hyb}x(p*,t))

x(p,t)=Wₒᵤₜr(t)

The equation r′==g (Ar+W_{hyb}x(p*, t)) in the above paragraph is an example of a simple, non-parametric reservoir ordinary differential equation, written as a neural ordinary differential equation. A is referred to as the weight matrix, W_{hyb}x(p*, t) is a “hybrid” term used to drive the reservoir, and x(p*, t) is a candidate solution at some point in the chosen parameter space. The function g is an activation function, which, in addition to the weight matrix A, is chosen to control the behavior of the full derivative term.

A CTESN implemented as described above may be trained as follows: first, a parameter space P is chosen, which is a cross product of ranges of the system parameters. This space is then sampled, yielding {p₁, . . . , pₙ}∈ P. The system is simulated at each of these parameters, yielding a training set of time series. The second equation in the paragraph above refers to the second step in the training. Projections {Wₒᵤₜ^{p}^{₁}, . . . , Wₒᵤₜ^{p}} are computed from the simulated reservoir r to each time series in the training set, using a QR decomposition or the singular value decomposition. Finally, an interpolating function p→>Wₒᵤₜ (p) is then fit. Prediction from the CTESN now follows three steps: (1) simulation of the reservoir; (2) constructing the projection; and (3) matrix-vector multiplication, as shown below.

\hat{x}(\hat{p},t)=Wₒᵤₜ(\hat{p})r(t)

While training the CTESN, the reservoir should be chosen strategically such that the time series from the reservoir matches key characteristics of the output time series, while being cheap to simulate. The above basic formulation may not be amenable to train systems that exhibit complex behavior. For instance, this reservoir is largely continuous, and may not accurately capture discontinuities. If the output time series contains a discontinuity at a point in time, the reservoir should also contain it.

A domain-specific choice of reservoir should be used that can accurately handle semi-discontinuous components seen in circuit simulations.

In embodiments of the methods and systems described herein, a variant of the CTESN formulation that incorporates external forcing may be used. The variant of the CTESN described herein may be used to capture system response to external forcing or internal disturbance. This training procedure not only trains on a bounded parameter space P like a conventional CTESN, but also on a space of external forcing functions.

For example, consider a bounded space of forcing functions F, such as a Fourier series or polynomials with a finite number of terms and a predefined range of coefficients. In other words, consider a bounded space of coefficients that describe a bounded space of functions. Let forcing functions {f₁, . . . fₙ} be sampled from this space. To incorporate forcing functions, the following equation:

r′=g(Ar+W_{hyb}x(p* , t))

which was described above, may thus be modified as follows:

r′=g(Ar+W_{hyb}x(p*, t)+W_{f}f(t))

where W_{f} is constant and f (t) is the additional forcing term. The reservoir r from the equation directly above is excited using each forcing function, resulting in a collection of reservoir response time series {r₁, . . . , rₙ}. The original system may also be excited with the same forcing functions, resulting in the time series collection {d, . . . , dₙ}. The least squares problem may be solved as follows:

$$\begin{matrix}arg min \\ {W}_{out}\end{matrix} {\sum }_{i} {( {W}_{out} {r}_{i} - {d}_{i} )}^{2}$$

To solve this numerically, all the system responses may be concatenated, as shown in the equation below, and then solve the equation below directly with a QR decomposition or the singular value decomposition:

Wₒᵤₜ[r₁|r₂|. . . |rₙ]=d₁|d₂|. . . |dₙ]

The resultant surrogate from this operation is referred to as the NR-CTESN. This composes naturally with the conventional CTESN training to learn a parametric surrogate. Namely, several sets of parameters may be sampled at pre-defined parameter space P, compute several projections from the reservoir system responses to the original system responses, and then learn the interpolating object Wₒᵤₜ (p). This procedure is summarized in the following method.

TABLE 1
Algorithm 1: Training the Nonlinear Response CTESN

Input: parameter space P , space of forcing functions F , pre-designed
reservoir r
Output:

| | |
|---|---|
| 1: | Sample {p₁,...pₙ} ∈ P,{f₁,...fₙ} ∈ F |
| 2: | for p in {p₁,...pₙ} do |
| 3: | Compute reservoir responses {r₁,...rₙ} and system responses |

{d₁,...dₙ} using {f₁,...fₙ}

| | |
|---|---|
| 4: | Fit projection matrix Wₒᵤₜ at parameter p using Wₒᵤₜ [r₁\|r₂\|...\|rₙ] = |
| | [d₁\|d₂\|...\|dₙ] |
| 5: | end for |
| 6: | Fit interpolator ψ: p → Wₒᵤₜ |
| 7: | return ψ, r |

In addition, system response to internal disturbances and events can be learned in the same way. Once the event in question is parametrized, a space of event parameters may be bounded and sampled, after which a projection can be fit in the same fashion as described above.

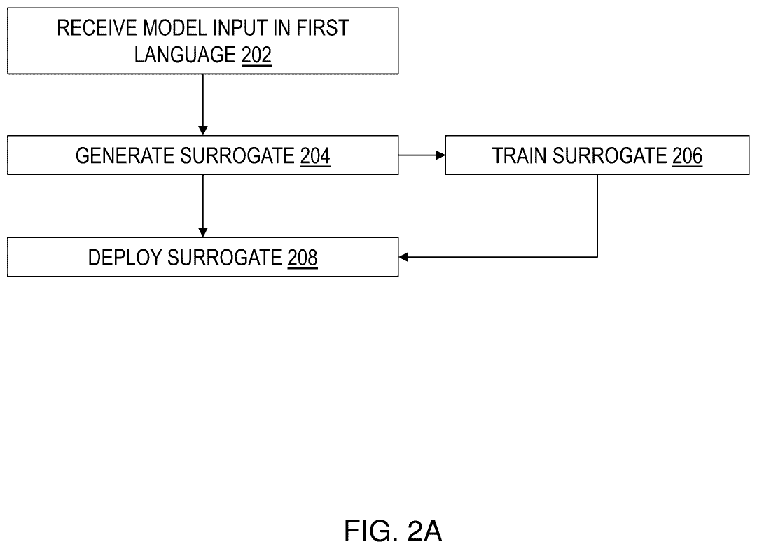

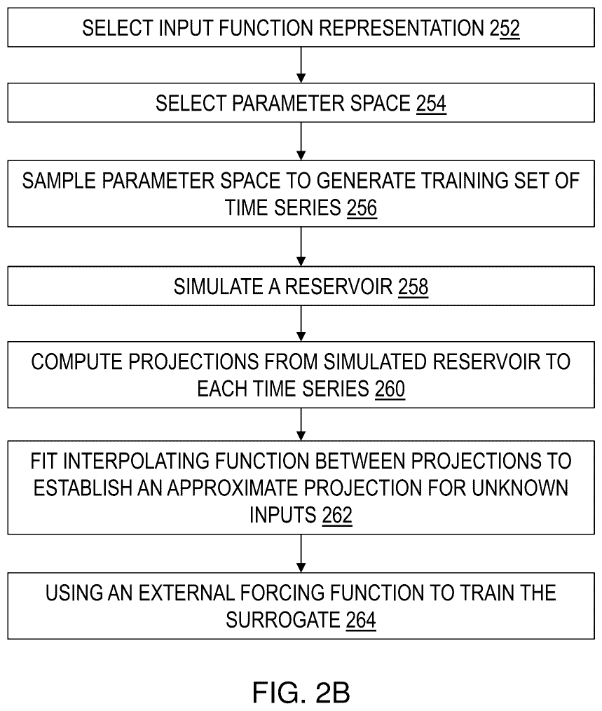

FIG. 2A depicts an exemplary process flow of a method for transforming a model of a first scientific computing language to a surrogate such that the surrogate is trained across a plurality of possible inputs. The method described in the context of FIG. 2A may be implemented by at least one processor or other circuitry in a computing device such as the exemplary computing device shown in FIG. 7 or a system comprising one or more computing devices such as the exemplary device shown in FIG. 7.

Referring to FIG. 2A, at step 202, the method includes receiving a model input in a first scientific computing language. In one embodiment, the first scientific computing language may be Modelica or Verilog-A. In other embodiments, the model input may be a proprietary model. The proprietary model may be a model in the Julia computing language. The model input may be a functional mockup unit (FMU) model. At step 204, the method includes generating a surrogate. In an embodiment, the generated surrogate may be of a second scientific computing language that is different from the first scientific computing language. The second scientific computing language may be the Julia computing language. In some embodiments, the generated surrogate may be generated using a Continuous Time Echo State Networks (CTESN) algorithm. The CTESN may be a linear projection CTESN (LPCTESN). The generation of the surrogate may be automated by simulation of FMUs using an FMU simulation layer. The generated surrogate may be an approximation that is built on a time series, or it may be an approximation that includes steady-state behavior of the received model input. At step 206, the generated surrogate may further be trained across a plurality of possible inputs. The step of training the surrogate across a plurality of possible inputs is further described in the context of FIG. 2B. In some embodiments, the training of the surrogate may be performed using machine learning. At step 208, the surrogate is deployed. If the surrogate was trained in step 206, then the surrogate that is deployed is the trained surrogate. If the surrogate was not trained in step 206, then the surrogate that is deployed is the generated surrogate. In some embodiments, deploying the surrogate may include connecting the surrogate with a separate user-defined model using a model composition framework. The model composition framework may be an acausal modeling framework, a causal modeling framework, a co-simulation framework, or a model exchange framework. In some embodiments, deploying the surrogate may include coupling the surrogate with a separate FMU model. In some embodiments, deploying the surrogate may include using the surrogate in an optimization loop for design.

FIG. 2B depicts an exemplary process flow of a method for training the surrogate across a plurality of possible inputs for scientific computing. Such a trained surrogate may be used for transforming a model in a first language to a surrogate in a second language for simulation. The method described in the context of FIG. 2B may be implemented by at least one processor or other circuitry in a computing device such as the exemplary computing device shown in FIG. 7 or a system comprising one or more computing devices such as the exemplary device shown in FIG. 7.

Referring to FIG. 2B, at step 252, the method includes selecting an input function representation. The input function representation is selected for each of one or more continuous input functions. Each input function representation is a finite parameter list.

At step 254, the method includes selecting a parameter space. The parameter space is a cross product of ranges of parameters, wherein the parameters comprise a concatenation of parameters of the original system and parameters of the input function representations. The concatenation of parameters of the original system and parameters of the input function representations is what the surrogate is being trained against. In some embodiments, the representations are selected to be coefficients of Chebyshev polynomials. In other embodiments, the representations are selected to be Fourier series amplitudes and frequencies. In still other embodiments, the representations are selected to be polynomial expansion coefficients.

At step 256, the method includes sampling the parameter space to generate a training set of time series for each parameter set.

At step 258, the method includes simulating a reservoir. In some embodiments, the simulated reservoir is selected such that the time series from the reservoir matches key characteristics of the output time series. In some embodiments, the simulated reservoir includes a discontinuity at a point in time in which the time series contains a discontinuity. In still other embodiments, the simulated reservoir is domain-specific.

At step 260, the method includes computing projections from the simulated reservoir to each time series in the training set. In some embodiments, the projections are computed using QR decomposition. In some embodiments, the projections are computed using singular value decomposition.

At step 262, the method includes fitting an interpolating function between the projections to establish an approximate projection for unknown input functions and parameter values.

At optional step 264, the method may further include using an external forcing function to train the surrogate. In some embodiments, the external forcing function is a Fourier series. In some embodiments, the external forcing function is a polynomial with a finite number of terms and a predefined range of coefficients. In some embodiments, the simulated reservoir is excited using the external forcing function.

### Circuit Simulation Applications: Inverter and Digital to Analog Converter (DAC)

The CTESN described herein has been trained to produce surrogate models of heating, ventilation, and air conditioning (HVAC) systems and quantitative systems pharmacology models. As an example of an application of the methods and systems of the NR-CTESN described herein, the methods and systems of the NR-CTESN described herein may be used to generate a surrogate of an inverter circuit. The inverter is designed using two Berkeley Short-channel IGFET Mode-4 (BSIM4) transistor models in CMOS inverter configuration. The input to this model is a 9-bit digital input with a fixed bit-width and the output is the flipped bitstream.

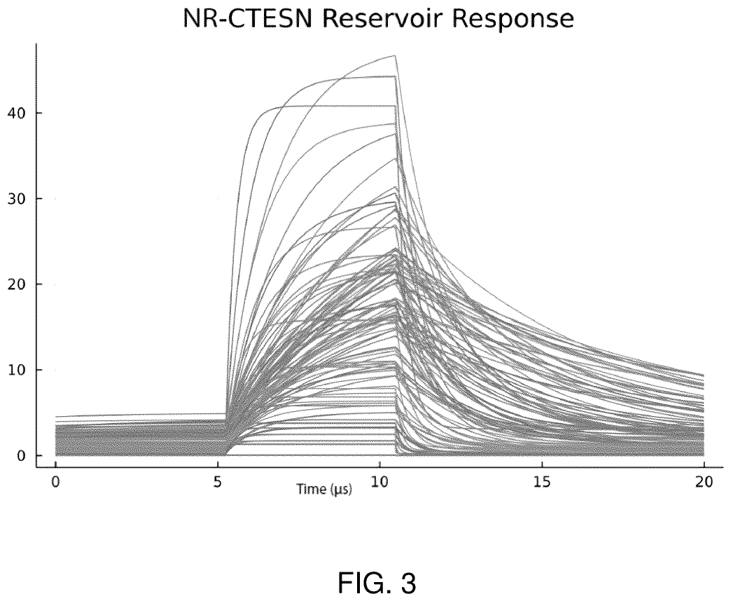

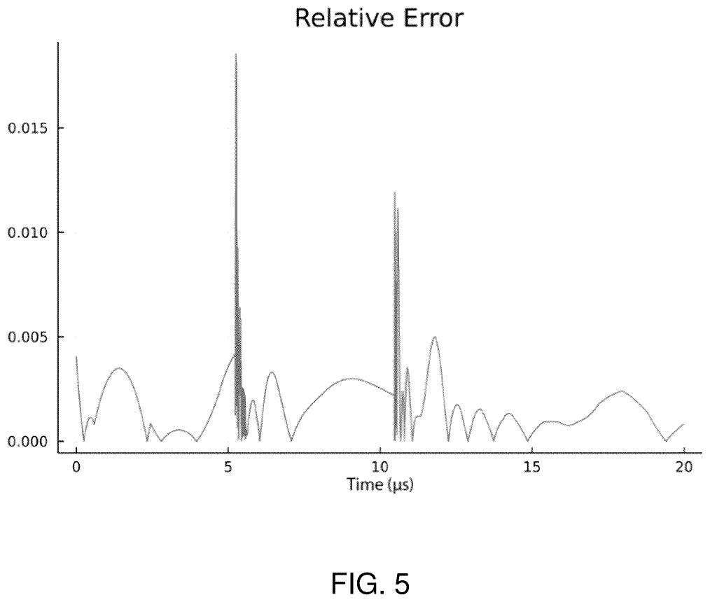

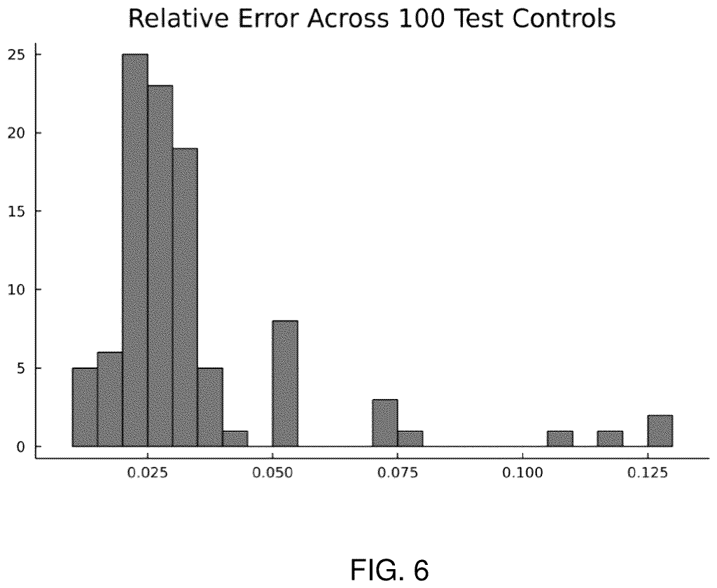

The first step in training a NR-CTESN is to design the reservoir. In general, the reservoir should exhibit a rich set of dynamics when excited by the digital inputs. The inverter is a mixed-signal circuit, and can output both analog and digital signals depending on its physical parameters. The reservoir must also follow this behavior. This was achieved by use of a domain-specific reservoir in the form of a Cellular Neural Network, which consists of a grid of cells. Each cell is a circuit with an RC element, with additional controlled current sources denoting coupling with its neighbors. The state equations are as follows:

$${Cv}_{ij}^{′} = - \frac{1}{{R}_{x}} {v}_{ij} + {\sum }_{C ( k , l ) ∈ {N}_{r} ( i , j )} A ( i , j ; k , l ) {v}_{ykl} + {\sum }_{C ( k , l ) ∈ {N}_{r} ( i , j )} B ( i , j ; k , l ) {v}_{ukl}$$

$${v}_{yij} = g ( {v}_{ij} )$$

where νᵢⱼ is the state of each cell C(i,j), the resistances Rₓ and capacitances C in each cell are randomly initialized, which allows them to create a range of responses. The output from each cell is the state of the cell νᵢⱼ filtered by an activation function g, chosen to be tanh in this example. Each cell also interacts with its neighbors via two template variables A and B, which dictate the weighted contribution from the neighbors' outputs ν_{ykl} and inputs νᵤₖₗ respectively. The size of the neighborhood Nᵣ(_{i,j}) controls the size of the two template variables. This coupling in the system produces a rich response shown in FIG. 3, below. For more details on the implementation, the reader is referred to the basic cellular neural network formulation in Chua, L. O.; and Yang, L. 1988b, Cellular neural networks: Theory, IEEE TRANSACTIONS ON CIRCUITS AND SYSTEMS, 35(10): 1257-1272, the entire contents of which is incorporated by reference herein. Since the input is 9-bit digital, there exist only 2⁹=512 possible discontinuous input signals to this system. The location of the discontinuity is controlled by inverter's system parameters, and the surrogate is trained on multiple sets of system parameters sampled using Latin Hypercube sampling. Additionally, it is trained with 100 inputs sampled from the possible 512. A 10×10 cellular network is randomly initialized and excited with the training inputs, and a neighborhood of 3×3 was chosen. The simulation time under consideration for training is 20 micro-seconds. A least-squares projection is then calculated between the reservoir system responses and the system responses of the original system. FIG. 5 shows a prediction plot of the surrogate at a test input while FIG. 6 shows the relative error, which is less than 2% over the whole time series. Additionally, a histogram of relative errors is shown plotted in FIG. 6. On the inverter example of 44 equations, a 9× acceleration of the simulation was achieved by the NR-CTESN. However, as demonstrated in previous work the CTESN architecture's acceleration increases as the size of the approximated system increases. To demonstrate this, we trained a surrogate using the same architecture on a Sky130 Digital to Analog Converter (DAC) simulated by Ngspice. This 1,200 equation system saw similar accuracy results but achieved a 274× acceleration, changing the simulation time from 7.3 hours to 16 minutes.

Thus, methods and systems for learning the response of arbitrary systems to external forcing or internal events are disclosed herein. The methods and systems presented are generalizable in that they are data-driven and place no constraints on the nature of the system being approximated. Science-guided or physics-informed priors are shown to be incorporated by the choice of reservoir. In general, however, the methods and systems described herein are agnostic to the system being learned. The resulting NR-CTESN surrogate is capable of generating nonlinear model order reductions of casual modeling blocks that match the reusable component architecture. This allows the NR-CTESN surrogate to automatically accelerate models from these types of modeling frameworks. When applied to the Functional Markup Interface (FMI) standard for causal models, a widely used binary form describing models in a way that matches the equation u′=φ(u,p,t,f (t)), the NR-CTESN can thus be used as an FMU-accelerator, taking in FMU binary descriptions of causal components and generating new FMU binaries which reproduce the behavior at a fraction of the cost. Given the hundreds of widely used tools throughout industry engineering which use this standard, this technique has the potential to make a large impact on the modeling industry.

FIG. 3 shows rich response dynamics of a domain-specific reservoir used in the NR-CTESN, used to generate the surrogate of the inverter. Each line represents an output from every cell in the cellular neural network.

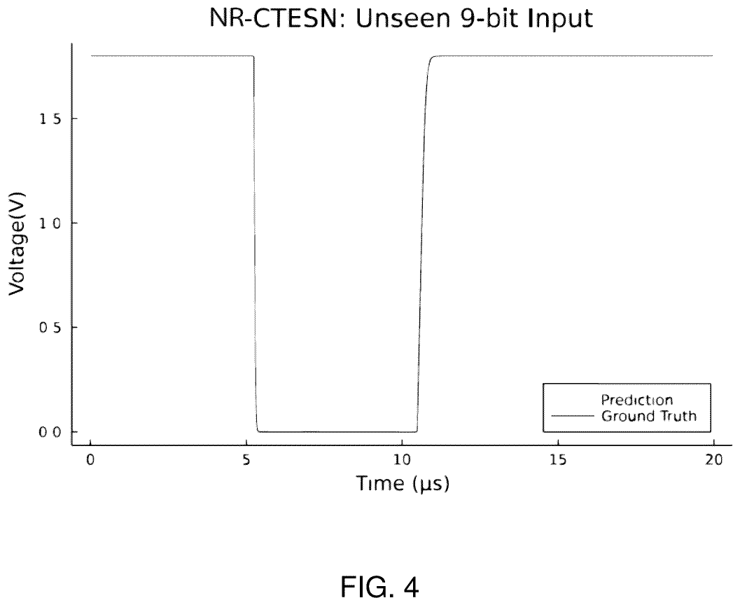

FIG. 4 shows a prediction of surrogate to unseen test input sequence. The solid line refers to the ground truth output from the inverter and the dashed line is the prediction. As can be seen from the fact that the two lines completely overlap, the NR-CTESN surrogate is able to predict the transition from high to low (and vice versa) at the correct times and is able to match the reference output.

FIG. 5 shows relative error of surrogate prediction at test input sequence. As can be seen, the error shown in FIG. 5 is the highest at the points of discontinuity, which are the places where the square signal transition from 0 to 1 and vice versa, as shown in FIG. 4.

FIG. 6 shoes a histogram of test errors. The X-axis denotes the relative error and Y-axis denotes the number of test samples with the same prediction error. As can be seen from FIG. 6, the majority of relative errors for the test dataset is less than 0.05.

As a practical application, the methods and computer systems described herein may be used, for example, for sustainable building simulation and design. Sustainable building simulation and design involves evaluating multiple options such as building envelope construction, Heating Ventilation, Air Conditioning and Refrigeration (HVAC/R) systems, power systems and control strategies. Traditionally, each such choice has been modeled independently by specialists drawing upon many years of development, using different tools, each with their own strengths. For example, the equation-oriented Modelica language allows modelers to express detailed Multiphysics descriptions of thermo-fluid systems. Other tools, such as EnergyPlus, DOE-2, ESP-r, and TRNSYS, have all been compared in the literature. These models are often coupled and run concurrently to make use of results generated by other models at runtime. For example, a building energy simulation model computing room air temperatures may require heating loads from an HVAC supply system, with the latter coming from a simulation model external to the building simulation tool. Thus, integration of these models into a common interface to make use of their different features, while challenging, is an important task.

The methods and computer systems described herein may be used to generate a surrogate of coupled room and cycle model in a building, measuring key outputs. Accuracy and reliability of the generated surrogate in the chosen input space can be demonstrated. Once generated, the generated surrogate is deployed in an optimization loop, convergence is examined, and the resulting acceleration in the design process is measured.

The surrogate generated as described herein accurately captures the dynamics of an HVAC cycle. For example, the surrogate prediction of the room temperature of a Room Air Conditioner (“RAC”) model compared may show minimal relative error as compared to the ground truth. Gradient-based local unconstrained optimization and global optimization are performed using the embedded surrogate, yielding a significant speedup to find the optimum.

### Surrogates of Coupled RAC Models

Consider the generation of a RAC model using the methods and computer systems described herein. It consists of a coupled room model with a vapor compression cycle model that removes heat from the room and dissipates it outside. The model is designed using components from the Modelica Buildings library. This model is written and exported from Dymola 2021 as a co-simulation FMU. The model is simulated for a timespan of an entire day at 100 sets of parameters, sampled from a chosen input space using Latin Hypercube sampling. The computer systems and methods described herein include an FMU simulation backend that runs these simulations in parallel and fits a CTESN to the time series data.

The performance of the surrogate that has been transformed using the methods and computer systems described herein to generate an approximating translation may achieve an error of <4% over the testing parameters while accelerating the simulation by 340×.

### Accelerating Global Optimization

Building design optimization has benefited from the use of surrogates by accelerating optimization by providing fast function evaluations as well as smoothing fitness functions with discontinuities. An average coefficient of performance across the time span may be used as a fitness value to maximize. This is calculated using output time series from the model, using the following formula:

$$COP ( t ) = \frac{{Q}_{tot} ( t )}{max ( 0.01 , CSP ( t ) )}$$

$${COP}_{avg} = \frac{{\sum }_{n = 1}^{{N}_{t}} COP ( {t}_{n} )}{{N}_{t}}$$

where COP refers to the coefficient of performance, COP_{avg} refers to the average coefficient of performance across the time interval (the quantity to optimize), Qₜₒₜ is the total heat dissipation from the coupled model, CSP(t) is the compressor shaft power, and Nₜ is the number of points in time sampled from the interval (720). An adaptive differential evolution global optimization algorithm may be used, which does not require the calculation of gradients or hessians.

The acceleration of the global optimization process using the methods and computer systems described herein allows the parameter optimization process to converge within 1% of the reference minimum value chosen, but may do so more than two orders of magnitudes faster than the model without surrogatization. Thus, the surrogate translation can be sufficiently accurate to be useful while providing a large acceleration to scientists and engineers attempting to use such models for design and controls.

FIG. 7 depicts a block diagram illustrating one embodiment of a computing device that implements the methods and systems for transforming a model in a first scientific computing language into a surrogatized model in a second scientific computing language described herein. Referring to FIG. 7, the computing device 700 may include at least one processor 702, at least one graphical processing unit (“GPU”) 704, a memory 706, a user interface (“UI”) 708, a display 710, and a network interface 712. The memory 706 may be partially integrated with the processor(s) 702 and/or the GPU(s) 704. The UI 708 may include a keyboard and a mouse. The display 710 and the UI 708 may provide any of the GUIs in the embodiments of this disclosure.

A person having ordinary skill in the art will recognize that the principles described herein may be applied to other physical systems not explicitly described herein, as the model described herein here provides a framework that is not specific to any particular physical system but rather can be used to build surrogates that represent components of any physical system.

The descriptions of the various embodiments of the technology disclosed herein have been presented for purposes of illustration, but these descriptions are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of transforming a model of a first scientific computing language to a surrogate of a second scientific computing language such that the surrogate is trained across a plurality of possible inputs, the method comprising:
receiving a model input,
wherein the model input is of a first scientific computing language;
generating a surrogate based on the received model input;
training the surrogate across a plurality of possible inputs, wherein training the surrogate comprises:
selecting an input function representation for each of one or more continuous input functions for the model input,
wherein each input function representation is a finite parameter list; selecting a parameter space,
wherein the parameter space is a cross product of ranges of parameters, and
wherein the parameters comprise a concatenation of parameters of the original system and parameters of the input function representations;
sampling the parameter space to generate a training set of time series for each parameter set;
simulating a reservoir;
computing projections from the simulated reservoir to each time series in the training set; and
fitting an interpolating function between the projections to establish an approximate projection for unknown input functions and parameter values; and
deploying the trained surrogate.

2. The method of claim 1, wherein the surrogate is of a second scientific computing language.

3. The method of claim 1, wherein the representations are selected to be coefficients of Chebyshev polynomials, Fourier series amplitudes and frequencies, or polynomial expansion coefficients.

4. The method of claim 1, wherein the projections are computed using QR decomposition or singular value decomposition.

5. The method of claim 1, wherein the simulated reservoir is selected such that the time series from the reservoir matches key characteristics of the output time series, wherein the simulated reservoir includes a discontinuity at a point in time in which the time series contains a discontinuity, or wherein the simulated reservoir is domain-specific.

6. The method of claim 1, further comprising using an external forcing function to train the surrogate.

7. The method of claim 1, wherein the model input is a proprietary model or a functional mockup unit (FMU) model.

8. The method of claim 1, wherein the surrogate is generated using a Continuous Time Echo State Networks (CTESN) algorithm.

9. The method of claim 1, wherein generating the surrogate is automated by simulation of FMUs using an FMU simulation layer.

10. The method of claim 1, wherein the training of the surrogate is performed using machine learning.

11. The method of claim 1, wherein deploying the trained surrogate includes connecting the trained surrogate with a separate user-defined model using a model composition framework, coupling the trained surrogate with a separate FMU model, or using the trained surrogate in an optimization loop for design.

12. The method of claim 1, wherein the first scientific computing language is Modelica or Verilog-A.

13. A computer system for transforming a model of a first scientific computing language to a surrogate of a second scientific computing language such that the surrogate is trained across a plurality of possible inputs, the computer system comprising:
a memory, and
a processor, the processor configured for:
receiving a model input,
wherein the model input is of a first scientific computing language;
generating a surrogate based on the received model input;
training the surrogate across a plurality of possible inputs, wherein training the surrogate comprises:
selecting an input function representation for each of one or more continuous input functions for the model input,
wherein each input function representation is a finite parameter list;
selecting a parameter space,
wherein the parameter space is a cross product of ranges of parameters, and
wherein the parameters comprise a concatenation of parameters of the original system and parameters of the input function representations;
sampling the parameter space to generate a training set of time series for each parameter set;
simulating a reservoir;
computing projections from the simulated reservoir to each time series in the training set; and
fitting an interpolating function between the projections to establish an approximate projection for unknown input functions and parameter values; and
deploying the trained surrogate.

14. The computer system of claim 13, wherein the surrogate is of a second scientific computing language.

15. The computer system of claim 13, wherein the representations are selected to be coefficients of Chebyshev polynomials, Fourier series amplitudes and frequencies, or polynomial expansion coefficients.

16. The computer system of claim 13, wherein the projections are computed using QR decomposition or singular value decomposition.

17. The computer system of claim 13, wherein the simulated reservoir is selected such that the time series from the reservoir matches key characteristics of the output time series, wherein the simulated reservoir includes a discontinuity at a point in time in which the time series contains a discontinuity, or wherein the simulated reservoir is domain-specific.

18. The computer system of claim 13, wherein the processor is further configured for using an external forcing function to train the surrogate.

19. The computer system of claim 13, wherein the model input is a proprietary model or a functional mockup unit (FMU) model.

20. The computer system of claim 13, wherein the surrogate is generated using a Continuous Time Echo State Networks (CTESN) algorithm.

21. The computer system of claim 13, wherein generating the surrogate is automated by simulation of FMUs using an FMU simulation layer.

22. The computer system of claim 13, wherein the transformation of the surrogate is performed using machine learning.

23. The computer system of claim 13, wherein deploying the trained surrogate includes connecting the trained surrogate with a separate user-defined model using a model composition framework, coupling the trained surrogate with a separate FMU model, or using the trained surrogate in an optimization loop for design.

24. The computer system of claim 13, wherein the first scientific computing language is Modelica or Verilog-A.
